(19) United States
(12) Patent Application Publication
(10) Pub. No.: US 2026/0045802 A1
(43) Pub. Date: Feb. 12, 2026

(54) ELECTRONIC DEVICE AND METHOD OF DRIVING SAME

(71) Applicant: Samsung Electronics Co., Ltd., Suwon-si (KR)

(72) Inventors: Sungyong KIM, Suwon-si (KR); Hyunjun OH, Suwon-si (KR); Hangseok CHOI, Suwon-si (KR)

(21) Appl. No.: 19/262,624

(22) Filed: Jul. 8, 2025

Related U.S. Application Data
(63) Continuation of application No. PCT/KR2025/009282, filed on Jul. 1, 2025.

(30) Foreign Application Priority Data
Aug. 7, 2024 (KR) 10-2024-0105534
Oct. 28, 2024 (KR) 10-2024-0148418

(51) Int. Cl. H02J 7/00; H03M 1/12; H04B 3/54

(52) U.S. Cl. CPC H02J 7/00032; H02J 7/0042; H04B 3/54; H03M 1/12

(57) ABSTRACT

An electronic device may perform designated communication with the external device through a cable, the designated communication including transmitting a first signal and receiving a second signal from the external device, calculating a difference value between a potential of the first signal and a potential of the second signal, determining, based on the calculated difference value and a change in a power voltage input to the electronic device, an impedance of the cable, determining, based on the determined impedance, a charging current, and request the external device to transmit the determined charging current.

### CROSS-REFERENCE TO RELATED APPLICATIONS

This application is a continuation of International Application No. PCT/KR2025/009282 designating the United States, filed on Jul. 1, 2025, in the Korean Intellectual Property Receiving Office and claiming priority to Korean Patent Application Nos. 10-2024-0105534, filed on Aug. 7, 2024, and 10-2024-0148418, filed on Oct. 28, 2024, in the Korean Intellectual Property Office, the disclosures of each of which are incorporated by reference herein in their entireties.

### BACKGROUND

### Field

The disclosure relates to an electronic device and a driving method thereof.

### Description of Related Art

A power supply device (e.g., a travel adapter (TA)) may perform power delivery communication with an electronic device via a cable and supply power to a power receiving device (e.g., a smart phone). The power receiving device (e.g., a smartphone) may use the power input from the power supply device to charge a battery of the power receiving device and provide power to a system (in other words, a load circuit) of the power receiving device. For example, the power input from the power supply device to the power receiving device may be distributed to the battery and system through a charging circuit of the power receiving device.

The above-described information may be provided as a related art to help understanding of the disclosure. No assertion or determination is made as to the applicability of any of the foregoing as prior art with respect to the disclosure.

If a cable connecting a power supply device and a power receiving devices is aged or not a designated genuine product, power delivery (PD) communication between the two devices may fail. Due to the resistance of the cable, an output voltage of the power supply (a voltage of a power signal output from the power supply to the cable) is relatively lower than an input voltage of the power receiving device (a voltage of a power signal input from the cable to the power receiving device). The voltage drop due to the resistance of the cable may be referred to as an IR drop (or, voltage (V) drop).

The tolerance for IR drops is defined in the USB PD. The USB power delivery (PD) is known as a communication protocol for supplying power between electronic devices connected through a USB cable. For example, in case that the output current (current of the power signal from the power supply to the cable) of the power supply is configured to a maximum of 5 A, the IR drop between power pins on two devices connected through a USB Type C cable may be allowed to be about 500 mV and the IR drop between ground pins may be allowed to be about 250 mV. If a cable is aged or not a designated genuine product, IR drops may occur beyond the predefined tolerance as described above.

The IR drop exceeding the tolerance may cause errors in PD communication between the two devices. For example, the power receiving device may perform PD communication with the power supply device to adjust the output voltage and/or the output current of the power supply device. While PD communication is performed, the power supply device may not identify data transmitted by the power receiving device. Accordingly, the power supply device may stop supplying power to the power receiving device. Thereafter, power supply may be restored through the PD communication between two devices. However, the power supply may be stopped again. As the power supply is repeatedly stopped and restarted, batteries are slow to charge, and voice of customer (VOC) complaints (e.g., users complaining that charging is slow or not possible) may follow.

### SUMMARY

Embodiments of the disclosure may provide an electronic device and a driving method thereof, which when a communication error is caused due to connection to a power supply device through an abnormal cable, may reduce the output current of the power supply device so that the communication error no longer occurs and the battery may be charged more quickly.

According to an example embodiment of the disclosure, an electronic device may include: a battery, a charging interface, comprising circuitry, configured to be connected to an external device through a cable, a first charger including a power converter comprising circuitry configured to increase a current supplied from the external device by a designated ratio to output the current and reduce a voltage supplied from the external device by the designated ratio to output the voltage, a second charger configured to function as a buck converter, a memory configured to store instructions, and at least one processor, comprising processing circuitry, wherein at least one processor, individually and/or collectively, is configured to execute the instructions and to cause the electronic device to: based on a connection with the external device being detected, perform designated communication with the external device through the cable, the designated communication including an operation in which the electronic device transmits a first signal and an operation in which the electronic device receives a second signal from the external device, calculate a difference value between a potential of the first signal and a potential of the second signal, determine, based on the calculated difference value and a change in a power voltage input to the electronic device, an impedance of the cable, determine, based on the determined impedance, a charging current, and request the external device to transmit the determined charging current.

According to an example embodiment of the disclosure, a method of driving an electronic device may include: based on a connection with an external device through a cable being detected, performing designated communication with the external device through the cable, the designated communication including an operation in which the electronic device transmits a first signal and an operation in which the electronic device receives a second signal from the external device, calculating a difference value between a potential of the first signal and a potential of the second signal, determining, based on the calculated difference value, an impedance of the cable, determining, based on the determined impedance, a charging current, and requesting the external device to transmit the determined charging current.

According to an example embodiment, an electronic device may include: a battery, an interface including a power terminal, a ground terminal, and a data terminal and configured to be connected to an external device through a cable, a detection circuit configured to measure a signal associated with a voltage of the data terminal, at least one charging circuit configured to charge the battery using external power supplied through the power terminal and the ground terminal, a memory configured to store instructions, and at least one processor, comprising processing circuitry, wherein at least one processor, individually and/or collectively, is configured to execute the instructions and to cause the electronic device to: detect connection with the external device, receive a second signal from the external device through the cable, identify a voltage value associate with the second signal through the detection circuit, determine, based on the voltage value associated with identified the second signal, a charging current, and request the external device to transmit the determined charging current.

According to various example embodiments of the disclosure, in case that a communication error is caused due to connection to a power supply device through an abnormal cable, the output current of the power supply device may be reduced so that the communication error no longer occurs and the battery may be charged more quickly.

In addition, various effects directly or indirectly identified through the disclosure may be provided.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of a power receiving device configured to charge a battery using power received from a power supply device according to various embodiments;

FIG. 3 is a diagram illustrating an example communication error due to IR drop according to various embodiments;

FIGS. 4A and 4B are graphs illustrating a first signal of an electronic device and a second signal of an external device according to various embodiments;

FIG. 5 is a flowchart illustrating an example operation of an electronic device according to various embodiments;

FIG. 6 is a flowchart illustrating an example method by which an electronic device compares a first signal and a second signal according to various embodiments

FIG. 7 is a block diagram illustrating an example configuration of various components of an electronic device for converting a second signal according to various embodiments;

FIG. 8 is a diagram illustrating an example process in which an electronic device converts a second signal according to various embodiments;

FIG. 9 is a flowchart illustrating an example operation in which an electronic device determines an impedance of a cable by comparing a high voltage level of each of a first signal and a second signal according to various embodiments;

FIG. 10 is a flowchart illustrating an example operation in which an electronic device determines an impedance of a cable by comparing a low voltage level of each of a first signal and a second signal according to various embodiments;

FIG. 11 is a flowchart illustrating an example operation in which an electronic device determines an impedance of a cable by comparing an amplitude of each of a first signal and a second signal according to various embodiments;

FIG. 12 is a flowchart illustrating an example operation of an electronic device according to various embodiments;

FIG. 13 is a diagram illustrating an example notification output from an electronic device according to various embodiments; and

FIG. 14 is a flowchart illustrating an example operation in which an electronic device determines an impedance of a cable according to various embodiments.

### DETAILED DESCRIPTION

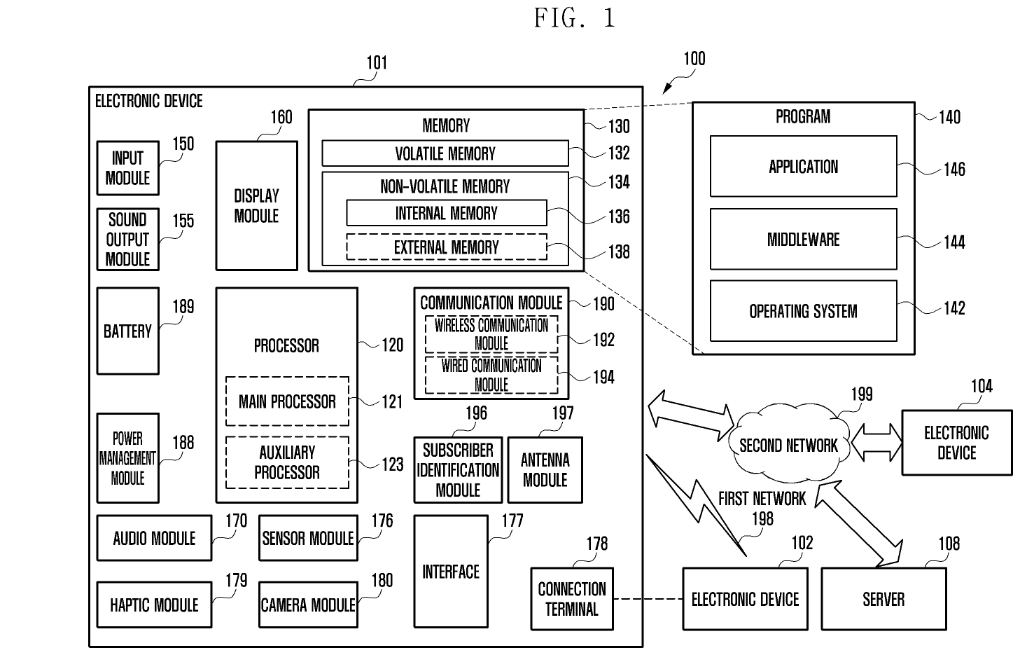

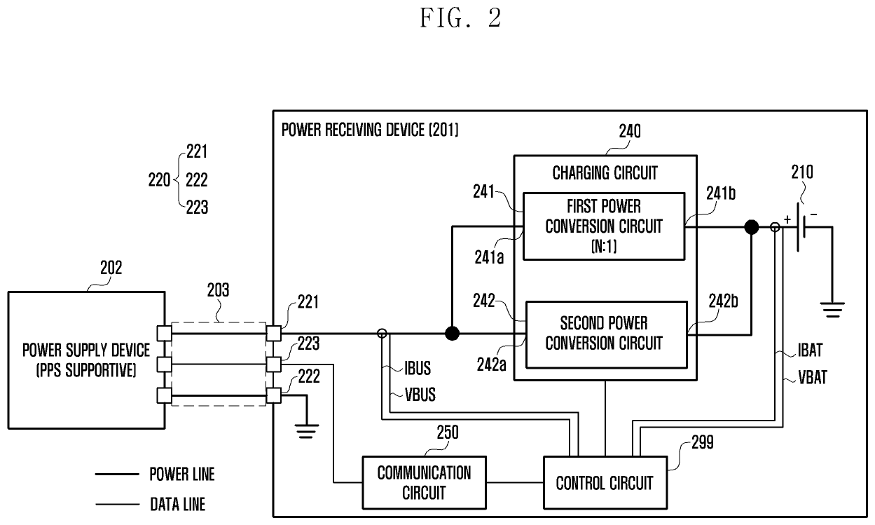

Each of the various example embodiments described with reference to the drawings of the disclosure may be independently configured as an embodiment. For example, each of an embodiment of FIG. 1 and an embodiment of FIG. 2 may be configured independently of each other. Each of the various embodiments described with reference to the drawings of the disclosure may be independently operated as an embodiment. For example, each of the embodiment of FIG. 1 and the embodiment of FIG. 2 may be configured independently of each other.

At least two embodiments described with reference to the drawings of the disclosure may be combined and configured. For example, at least a portion of the example embodiment of FIG. 1 and at least a portion of the example embodiment of FIG. 2 may be combined and configured. At least two embodiments described with reference to the drawings of the disclosure may be combined and operated. For example, at least a portion of the embodiment of FIG. 1 and at least a portion of the embodiment of FIG. 2 may be combined and operated.

In case that at least two embodiments described with reference to the drawings of the disclosure are combined, at least some of the configurations and/or at least some of the operations included in each embodiment may be omitted. For example, in case that the example embodiment of FIG. 1 is combined with the example embodiment of FIG. 2, at least some of the configurations and/or at least some of the operations included in the embodiment of FIG. 1 may be omitted, and at least some of the configurations and/or at least some of the operations included in the embodiment of FIG. 2 may be omitted.

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

FIG. 2 is a block diagram illustrating an example configuration of a power receiving device 201 configured to charge a battery using power received from a power supply device 202 according to various embodiments. The power receiving device 201 may be connected to the power supply device 202 through a cable (e.g., a USB type-C cable) 203 configured to support data communication and power reception.

The term “power supply device 202” as used in various embodiments of the disclosure may refer to a charging device that outputs power through a cable 203 and may be used interchangeably with terms such as external device.

The term “power receiving device 201” as used in various embodiments of the disclosure may refer to a device that receives power through a cable 203 and may correspond to, for example, the electronic device 101 described with reference to FIG. 1.

Referring to FIG. 2, the power receiving device 201 (e.g., the electronic device 101 in FIG. 1 or the power receiving device 201 in FIG. 2) may include a battery 210 (e.g., the battery 189 in FIG. 1), a connector 220, a charging circuit 240, a communication circuit 250, and a control circuit 299 (e.g., the processor (e.g., including processing circuitry) 120 in FIG. 1).

According to an embodiment, the connector 220 (e.g., the connection terminal 178 in FIG. 1) may include a power terminal 221 configured to receive a power signal from the power supply device 202, a ground terminal 222 connected to a ground of the power receiving device 201, and a data terminal 223 configured to perform data communication with the power supply device 202. By way of example, the connector 220 may include a socket according to a universal serial bus (USB) type-C. The socket 203 of the connector 220 may be coupled to a plug. For example, among pins of the USB Type-C socket, a VBUS pin may be used as the power terminal 221 and a configuration channel (CC) pin and/or differential signal pins (DP(D+), DN(D−)) may be used as the data terminal 223.

The term “connector 220” as used in various embodiments of the disclosure may be used interchangeably with terms such as charging interface.

According to an embodiment, the charging circuit 240 may support constant current (CC) and constant voltage (CV) charging, based on control of the control circuit 299. For example, while a charging mode is configured to a CC mode, the charging circuit 240 may, in case that a voltage of the battery 210 (e.g., a voltage difference between an anode and cathode of the battery) is less than a designated target voltage value, maintain a constant current of the power signal output from the charging circuit 240 at a charging current value configured by the control circuit 299. For example, the target voltage value may refer to as a voltage of the battery 210 when the battery is fully charged. The full charge may refer to a state of charge (SOC) when the amount of charge in a battery has reached a configured maximum capacity of 100%, without risk of burnout or explosion. For another example, the target voltage may correspond to a designated voltage (e.g., a voltage corresponding to 98% of maximum capacity).

According to an embodiment, the control circuit 299 may, when a voltage VBAT of the battery 210 reaches a target voltage value while the battery is being charged, switch the charging mode into a CV mode. When the voltage VBAT of the battery 210 reaches the target voltage value, thereby switching the charging mode from the CC mode to the CV mode, the charging circuit 240 may, based on control of the control circuit 299, reduce the current value of the power signal output from the charging circuit 240 to ensure that the input voltage VBAT of the battery module 210 is maintained at the target voltage value. While the battery module 210 is being charged in the CV mode, if the current IBAT of the power signal input from the charging circuit 240 to the battery 210 is reduced to a designated current value (e.g., a topoff current value) for completion of the charge, the charging circuit 240, based on control of the control circuit 299, may complete charging of the battery 210 by stopping the output of the power signal to the battery 210.

The term “control circuit 299” as used in various embodiments of the disclosure may correspond to the processor 120 described with reference to FIG. 1. The term “control circuit 299” as used in various embodiments of the disclosure may correspond to a control circuit included in the power management module 188 and/or the interface 177 in FIG. 1.

According to an embodiment, the charging circuit 240 may include a first power conversion circuit (paraphrased, a direct charging circuit) 241 and a second power conversion circuit (paraphrased, a switching charging circuit) 242.

According to an embodiment, the first power conversion circuit 241 may include a first terminal 241a and a second terminal 241b to or from which power is input or output. The first terminal 241a may be electrically connected to the power terminal 221 (e.g., the VBUS terminal) of the connector 220. The second terminal 241b may be electrically connected to the anode of the battery 210. The cathode of the battery 210 may be connected to the ground of the power receiving device 201. The first power conversion circuit 241 may be configured to convert a voltage value of the power signal input from the first terminal 241a with a fixed voltage conversion ratio (a ratio of a voltage value of the input power signal to a voltage value of the output power signal) and transmit same to the second terminal 241b. The first power conversion circuit 241 may include a circuit (e.g., a switched capacitor voltage divider (SCVD)) configured such that the ratio of the output power to the input power is “1.” For example, the first power conversion circuit 241 may convert the voltage value of the power signal received from the power terminal 221 through the first terminal 241a to N to 1 (e.g., step down 1/N times), convert the current value to 1 to N (e.g., step up N times), and output the power signal to the battery 210 through the second terminal 241b.

The term “first power conversion circuit 241” as used in various embodiments of the disclosure may be used interchangeably with terms such as first charger.

According to an embodiment, the second power conversion circuit (e.g., a buck converter) 242 may include a third terminal 242a and a fourth terminal 242b to or from which power is input or output. Here, “third” and ‘“fourth” are prefixes used to distinguish from the terminals 241a and 241b configured in the first power conversion circuit 241, and do not define the second power conversion circuit 242 in any other respect. The third terminal 242a may be electrically connected to the power terminal 221 of the connector 220. The fourth terminal 242b may be electrically connected to the anode of the battery 210. The second power conversion circuit 242 may convert a voltage value and/or a current value of the power signal input from the third terminal 242a and transmit same to the fourth terminal 242b. For example, the second power conversion circuit 242 may step up or step down the voltage value of the power signal received from the power terminal 221 through the third terminal 242a and transmit the power signal to the battery 210 through the fourth terminal 242b.

The term “second power conversion circuit 242” as used in various embodiments of the disclosure may be used interchangeably with terms such as second charger.

According to an embodiment, the communication circuit (e.g., a USB controller) 250 may identify a type of an external device connected to the connector 220, based on data received from the external device through the data terminal 223. The communication circuit 250 may transmit, to the control circuit 299, identification information indicating the type of the external device. The control circuit 299 may, based on the identification information, perform communication with the external device through the communication circuit 250 according to the power delivery (PD) communication protocol to perform an operation of determining a source supplying power and a sink receiving power from among two devices 201 and 202. For example, when the power supply device 202 is recognized as a travel adapter (TA), the power supply device 202 may be determined as the source and the power receiving device 201 may be determined as the sink. After the negotiation, the control circuit 299 may perform communication with the power supply device 201 through the communication circuit 250 according to the PD communication protocol (e.g., power data objects (PDO) or programmable power supply (PPS)) to perform an operation of negotiating a current value and/or a voltage value of a power signal to be transmitted from the power supply device 202. The control circuit 299 may control one of the power conversion circuits 241 and 242 to output a power signal having the voltage value and the current value determined by a result of the negotiation. For example, in case that the power supply device 202 is identified as a PPS-enabled device, the control circuit 299 may deactivate the second power conversion circuit 242 and activate the first power conversion circuit 241 and may supply power to the battery 210 using the activated first power conversion circuit 241. For another example, in case that the power supply device 202 is identified as a PPS-unsupported device, the control circuit 299 may deactivate the first power conversion circuit 241 and activate the second power conversion circuit 242 and may supply power to the battery 210 using the activated second power conversion circuit 242.

According to an embodiment, the control circuit 299 may include a component (e.g., a microcontroller unit (MCU)) of a PMIC (e.g., the power management module 188) or a component (e.g., an application processor) of a processor (e.g., the processor 120 of FIG. 1).

According to an embodiment, at least one of the first power conversion circuit 241, the second power conversion circuit 242, the communication circuit 250, and the control circuit 299 may be components integrated on a particular chip (e.g., an interface integrated (IF) PMIC).

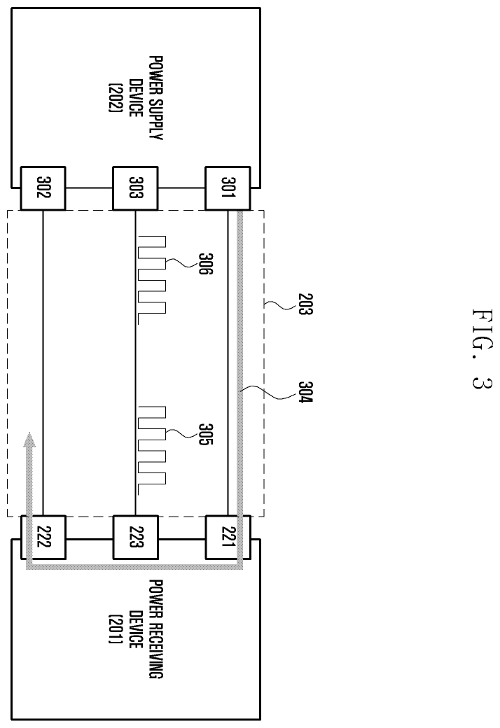

FIG. 3 is a diagram illustrating an example communication error due to IR drop according to various embodiments.

Referring to FIG. 3, when the power is supplied from the power supply device 202 (e.g., the power supply device 202 in FIG. 2) to the power receiving device 201 (e.g., the power receiving device 201 in FIG. 2), a current 304 flows from the power terminal 301 (e.g., the VBUS terminal) of the power supply device 202 to the power terminal 221 (e.g., the VBUS terminal) of the power receiving device 201 and returns to the ground terminal 302 of the power supply device 202 via the ground terminal 222 of the power receiving device 201. While the current 304 flows between the power supply device 202 and the power receiving device 201, communication for adjusting a current value may be performed between two devices 201 and 202. For example, data 305 may be output from the data terminal 223 of the power receiving device 201 to the data terminal 303 of the power supply device 202. For example, data 306 may be output from the data terminal 303 of the power supply device 202 to the data terminal 223 of the power receiving device 201. In various embodiments of the disclosure, the data 305 output from the data terminal 223 of the power receiving device 201 to the data terminal 303 of the power supply device 202 may be referred to as a first signal 305. In various embodiments of the disclosure, the data 306 output from the data terminal 303 of the power supply device 202 to the data terminal 223 of the power receiving device 201 may be referred to as a second signal 306.

According to an embodiment, a VBUS voltage, which is a power voltage output from the power terminal 301 (e.g., the VBUS terminal) of the power supply device 202, may be subject to IR drop in the cable 203, which may result in a lower VBUS voltage being recognized at the power terminal 221 of the power receiving device 201. For example, a VBUS voltage, which is a power voltage output from the power terminal 301 (e.g., the VBUS terminal) of the power supply device 202, is output at about 9 volts, but the VBUS voltage recognized at the power terminal 221 of the power receiving device 201 may be about 8.3 volts. Accordingly, when the communication between two devices 201 and 202 is established, a ground voltage level recognized by each of the two devices 201, 202 may be different, which may be the cause of communication errors. For example, the deviation in ground voltage levels recognized by each of the two devices 201 and 202 may be greater if the cable 203 is aged or not a designated genuine product. According to an embodiment, when the charging current 304 is higher (e.g., the charging current is equal to or greater than 3 A), the cable 203 between the power supply device 202 and the power receiving device 201 has a high impedance, which may increase the IR drop and further increase the possibility of communication errors due to deviations in ground voltage levels. For example, in case that the cable 203 is aged or not a designated genuine product, as the charging current increases, the IR drop may exceed the prescribed allowance. Therefore, before the current value (or power value) of the power signal output from the power supply device 202 reaches the configured target value, the communication between the two devices 201 and 202 may fail and the power supply may be temporarily interrupted. The communication error may be repeated, resulting in a relatively slow charging of the battery 210. According to various embodiments of the disclosure, in case that the cable 203 is aged or not a designated genuine product, operations may be performed in the power receiving device 201 to prevent and/or reduce further communication errors and to charge the battery 210 rapidly by lowering the target value (e.g., a target charging current or maximum charging current). The identical type of communication error may refer to a repeated communication error when the current value (or power value) of the power signal output from the power supply device 202 is in a predetermined range. For example, the output current may rise in a stepwise manner and is in the predetermined current range (e.g., about 3.4 A to about 3.6 A) without reaching the target current value (e.g., about 5 A), and the communication error may be repeated. For another example, in case that the output power rises in a stepwise manner and belongs to a predetermined power range without reaching the target power value (e.g., about 40 W), the error may be repeated.

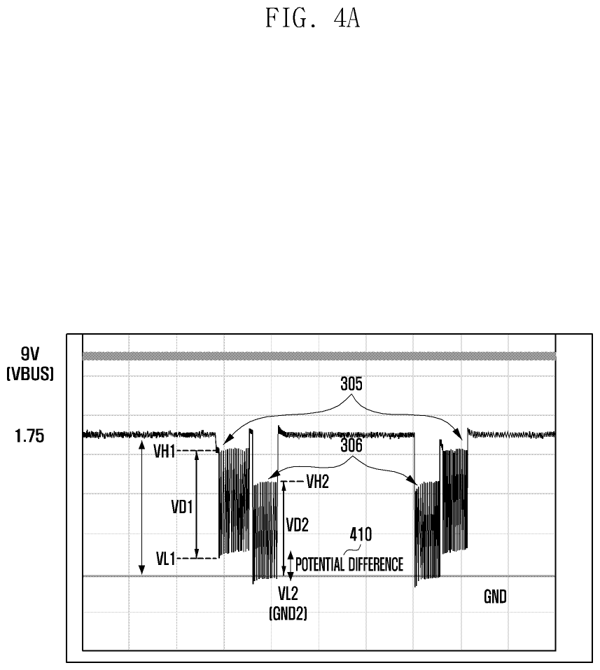

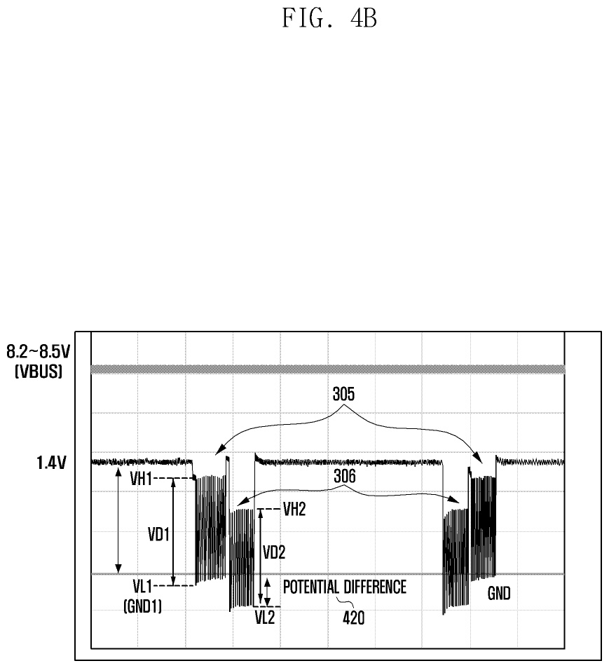

FIGS. 4A and 4B are graphs illustrating a first signal 410 of an electronic device 101 and a second signal 420 of an external device 202 according to various embodiments. For example, FIG. 4A is a waveform view illustrating the first signal 305 and the second signal 306 in the external device 202 (e.g., the power supply device 202 in FIG. 2). For example, FIG. 4B is a waveform view illustrating the first signal and the second signal in the electronic device 101 (e.g., the power receiving device 201 in FIG. 2).

Referring to FIGS. 4A and 4B, according to an embodiment, the electronic device 101 (e.g., the electronic device 101 in FIG. 1 or the power receiving device 201 in FIG. 2) may, in case that connection with the external device (e.g., the power supply device 202 in FIG. 2) through the cable (e.g., the 203 in FIG. 2) is detected, perform designated communication with the external device 202. The designated communication may correspond to communication according to the PD communication protocol (e.g., power data objects (PDO) or programmable power supply (PPS)). The electronic device 101 may perform an operation of negotiating a current value and/or a voltage value of a power signal to be transmitted by the external device 202 by performing the designated communication.

According to an embodiment, the designated communication that the electronic device 101 performs with the external device 202 may include, as at least a portion of the negotiation operation, an operation of the electronic device 101 transmitting the first signal 305 to the external device 202, and an operation of the electronic device 101 receiving the second signal 306 from the external device 202.

According to an embodiment, the first signal 305 transmitted by the electronic device 101 to the external device 202 may include a “Request signal.” For example, the Request signal may correspond to a signal from the electronic device 101 requesting the current value and/or the voltage value of the power signal from the external device 202. The electronic device 101 may transmit at least a portion of requests for a 5V PDO, a 9V PDO, and a PPS PDO for PPS charging via the first signal 305 during an initial period of time (e.g., pre cc period) when the connection with the external device 202 is initiated.

According to an embodiment, the first signal 305 transmitted by the electronic device 101 to the external device 202 may include a “Good CRC signal.” For example, the Good CRC signal may be a signal indicating that the second signal 306 of the external device 202 is normally received, and the disclosure is not limited the definition.

According to an embodiment, the second signal 306 transmitted by the external device 202 to the electronic device 101 may include a “Source Cap signal.” For example, the Source Cap signal may be a signal output by the external device 202 initially connected to the electronic device 101, and may be a signal indicating an option of the current value and/or voltage value that the external device 202 may output, and the disclosure is not limited the definition.

According to an embodiment, the second signal 306 transmitted by the external device 202 to the electronic device 101 may include an “Accept signal.” The Accept signal may be a signal indicating that the electronic device 101 has completed a configuration of the requested current value and/or voltage value, and the disclosure is not limited the definition.

According to an embodiment, the second signal 306 transmitted by the external device 202 to the electronic device 101 may include an “Accept signal.” The Accept signal may be a signal indicating a response to output the requested current value and/or voltage value by the electronic device 101, and the disclosure is not limited the definition.

According to an embodiment, the second signal 306 transmitted by the external device 202 to the electronic device 101 may include an “PS RDY signal.” The PS RDY signal may be a signal indicating that the electronic device 101 has completed an output configuration of the requested current value and/or voltage value, and the disclosure is not limited the definition.

According to an embodiment, the second signal 306 transmitted by the external device 202 to the electronic device 101 may include an “Good CRC signal.” For example, the Good CRC signal may be a signal indicating that the first signal 305 of the electronic device 101 is normally received, and the disclosure is not limited the definition.

According to an embodiment, a VBUS voltage, which is a power voltage output from the power terminal (e.g., the power terminal 301 in FIG. 3) (e.g., the VBUS terminal) of the external device 202 (e.g., the power supply device 202 in FIG. 3), may be subject to IR drop in the cable (e.g., the cable 203 in FIG. 2), which may result in a lower VBUS voltage being recognized at the power terminal (e.g., the power terminal 221 in FIG. 3) of the electronic device 101 (e.g., the power receiving device 201 in FIG. 3). For example, a VBUS voltage, which is a power voltage output from the power terminal (e.g., the power terminal 301 in FIG. 3) (e.g., the VBUS terminal) of the external device 202, is output at about 9 volts, but the VBUS voltage recognized at the power terminal 221 of the electronic device 101 may be about 8.3 volts. Accordingly, when the communication between two devices 101 and 102 is established, a ground voltage level recognized by each of the two devices 101, 102 may be different, which may be the cause of communication errors. For example, a ground voltage level recognized in the electronic device 101 may be lower than a ground voltage level recognized in the external device 202, and the variation may become bigger when the cable 203 is aged or not a designated genuine product.

According to an embodiment, the first signal 305 transmitted by the electronic device 101 to the external device 202 may be a signal that swings between a low voltage level (or low level) corresponding to VL1 and a high voltage level (or high level) corresponding to VH1. For example, an amplitude of the low voltage level VL1 and the high voltage level VH1 of the first signal 305 may be VD1. Here, the low voltage level VL1 of the first signal 305 may be a ground (GND) level and may be defined as, for example, a first ground GND1 of the electronic device 101.

According to an embodiment, the second signal 306 transmitted by the external device 202 to the electronic device 101 may be a signal that swings between a low voltage level (or low level) corresponding to VL2 and a high voltage level (or high level) corresponding to VH2. For example, an amplitude of the low voltage level VL2 and the high voltage level VH2 of the second signal 306 may be VD2, and the amplitude VD2 of the second signal 306 may be different from the amplitude VD1 of the first signal 305. The low voltage level VL2 of the second signal 306 may be a ground (GND) level and may be defined as, for example, a second ground GND2 of the external device 202. The second ground GND2, which is the low voltage level VL2 of the second signal 306, needs to be substantially identical to the first ground GND1, which is the low voltage level VL1 of the first signal 305, but may be different due to IR drop in the cable 203. For example, the low voltage level VL1 of the first signal 305 in the VBUS of the electronic device 101 may be higher than the low voltage level VL2 of the second signal 306. The difference between the voltage level of the first ground GND1 and the voltage level of the second ground GND2 may, as described above, cause a communication error between the electronic device 101 and the external device 202. For example, the electronic device 101 may determine a high level or low level of the second signal 306 based on the voltage level of the first ground GND1. However, due to the IR drop of the cable 203, the operation of the electronic device 101 to determine the high level or low level of the second signal 306 recognized by the electronic device 101 may be inaccurate.

In FIGS. 4A, 410 is a potential difference between voltage levels of the first signal 305 recognized by the external device 202 and the second ground GND2 recognized by the external device 202.

In FIGS. 4B, 420 is a potential difference between voltage levels of the first signal 305 recognized by the electronic device 101 and the first ground GND1 recognized by the electronic device 101.

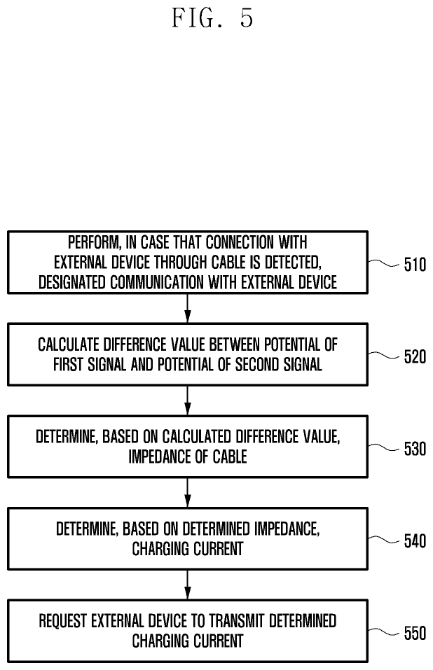

FIG. 5 is a flowchart illustrating an example operation of an electronic device 101 according to various embodiments.

Operations described in FIG. 5 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 5.

At least a portion of the operations illustrated in FIG. 5 may be omitted. At least some of the operations described with reference to other drawings in this disclosure may be added or inserted before or after at least some of the operations shown in FIG. 5.

According to an embodiment, at least some of the operations described in FIG. 5 may be performed sequentially.

According to an embodiment, at least some of the operations described in FIG. 5 may be performed in parallel (concurrently).

Hereinafter, an operation of the electronic device 101 according to an example embodiment will be described with reference to FIG. 5.

In operation 510, according to an embodiment, the electronic device 101 (e.g., the electronic device 101 in FIG. 1 or the power receiving device 201 in FIG. 2) may perform communication with an external device (e.g., the power supply device 202 in FIG. 2) according to the PD communication protocol (e.g., power data objects (PDO) or programmable power supply (PPS)). When the connection with the external device 202 (e.g., the power supply device 202 in FIG. 2) is initiated, the electronic device 101 may perform requests for a 5V PDO, a 9V PDO, and a PPS PDO for PPS charging. During at least some of periods of performing the requests of the 5V PDO, the 9V PDO, and the PPS PDO for the PPS charging, the electronic device 101 may transmit the first signal 305 to the external device 202 and receive the second signal 306 from the external device 202.

In operation 520, according to an embodiment, the electronic device 101 may calculate a difference value between a potential of the first signal 305 and a potential of the second signal 306 while performing the communication with the external device 202 according to the PD communication protocol (e.g., power data objects (PDO) or programmable power supply (PPS)). According to various embodiments, the electronic device 101 may be operable to calculate the difference value of the potentials in various ways. According to an embodiment, the electronic device 101 may identify a difference between the second signal 306 and the first ground GND1. According to an embodiment, the electronic device 101 may identify the low voltage level VL2 of the second signal 306. According to an embodiment, the electronic device 101 may identify an inverted high-level signal of the second signal 306.

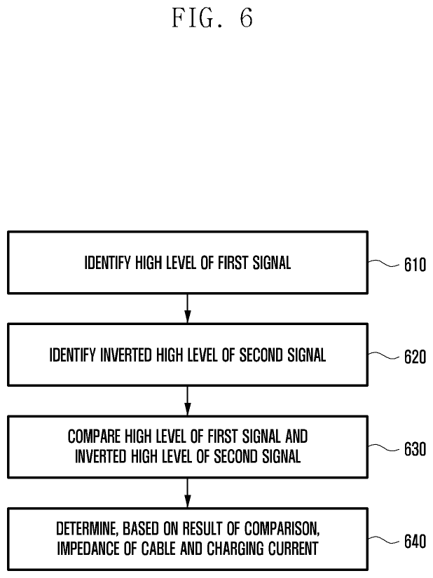

For example, the electronic device 101 may compare the high level (e.g., VH1 in FIG. 4) of the first signal 305 with the inverted high level (e.g., VL2 in FIG. 4) of the second signal 306, and the operations of the electronic device 101 will be described in greater detail below with reference to FIG. 6.

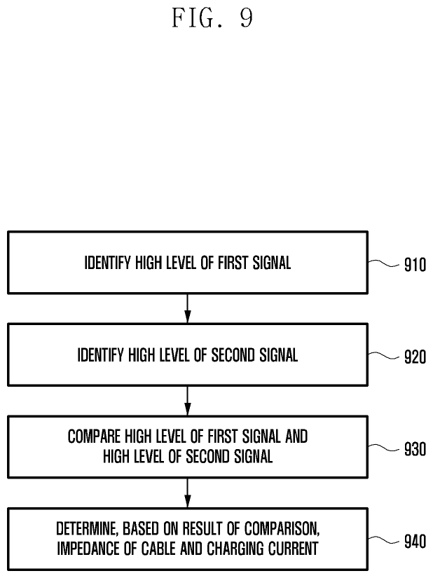

For example, the electronic device 101 may compare the high level (e.g., VH1 in FIG. 4) of the first signal 305 with the high level (e.g., VH2 in FIG. 4) of the second signal 306, and the operations of the electronic device 101 will be described in greater detail below with reference to FIG. 9.

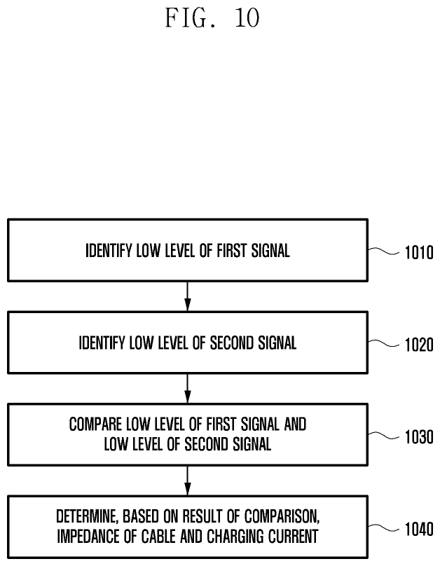

For example, the electronic device 101 may compare the low level (e.g., VL1 in FIG. 4) of the first signal 305 with the low level (e.g., VL2 in FIG. 4) of the second signal 306, and the operations of the electronic device 101 will be described in greater detail below with reference to FIG. 10.

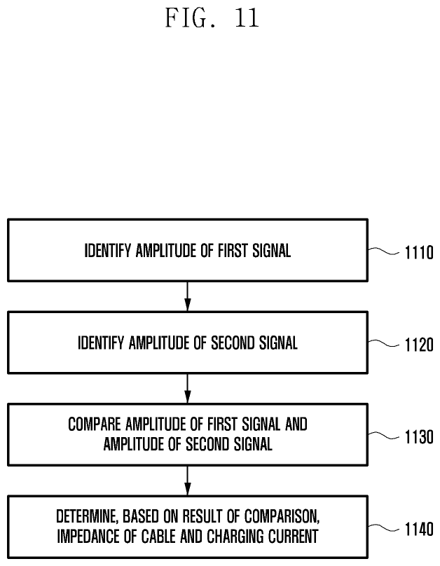

For example, the electronic device 101 may compare the amplitude (e.g., VD1 in FIG. 4) of the first signal 305 with the amplitude (e.g., VD2 in FIG. 4) of the second signal 306, and the operations of the electronic device 101 will be described in greater detail below with reference to FIG. 11.

In operation 530, the electronic device 101 according to an embodiment may determine an impedance of the cable 203 based on the difference value between the potential of the first signal 305 and the potential of the second signal 306. For example, while the electronic device 101 is performing the communication with the external device 202 according to the PD communication protocol (e.g., power data objects (PDO) or programmable power supply (PPS)), the low level (e.g., the voltage level on the second ground GND2) of the second signal 306 measured at the data terminal 223 of the electronic device 101 may gradually drop to a lower potential as the current of the power signal transmitted by the external device 202 increases, which is due to an IR drop in the cable 203. According to an embodiment, the electronic device 101 may estimate the impedance of the cable 203 using the difference value between the potential of the first signal 305 and the potential of the second signal 306.

According to an embodiment, the electronic device 101 may measure a deviation between the ground level of the first signal 305 and the ground level of the second signal 306. According to an embodiment, the electronic device 101 may measure a ΔV value recognized at the power terminal 221 of the electronic device 101 when the charging current (e.g., 304 in FIG. 3) is increased in a stepwise manner while keeping the voltage requested from the external device 202 fixed in the pre-cc section, which is the early section of the PPS. In this case, the ΔV value may refer to “a voltage change at the power terminal 221—the deviation between the ground level of the first signal 305 and the ground level of the second signal 306 measured at the data terminal 223.” For example, while the voltage output by the external device 202 is fixed, the VBUS voltage at the power terminal 221 of the electronic device 101 gradually drops as the charging current (e.g., 304 in FIG. 3) increases. When the voltage output from the external device 202 is fixed, the impedance value of the cable (e.g., 203 in FIG. 2) may be calculated by calculating a voltage drop according to a current change amount in the electronic device 101.

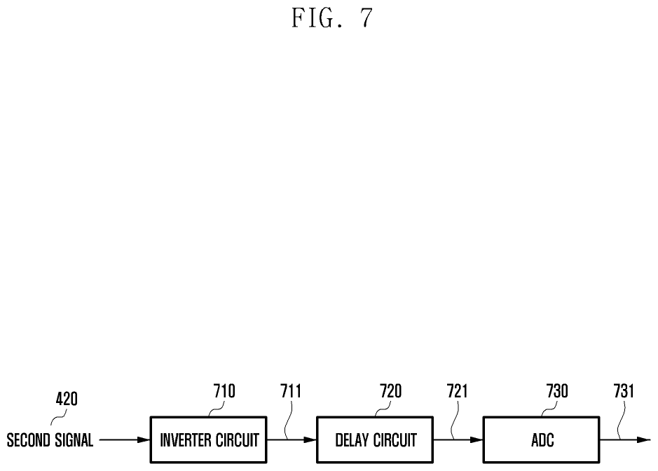

According to an embodiment, when the charging current (e.g., 304 in FIG. 3) is increased in a stepwise manner in the pre-cc section, which is the early section of the PPS, an ADC (e.g., the ADC 730 in FIG. 7) included in the electronic device 101 may be used. According to an embodiment, the electronic device 101 may determine the deviation of the ground level of the first signal 305 and the ground level of the second signal 306 measured at the VBUS and data terminal 223 recognized at the power terminal 221, and then increase the charging current (e.g., 304 in FIG. 3) in a stepwise manner to determine the deviation of the ground level of the first signal 305 and the ground level of the second signal 306 measured at the VBUS and data terminal 223 recognized at the power terminal 221. According to an embodiment, the electronic device 101 may calculate the impedance of the cable 203 based on identifying a change in the VBUS potential difference and a change in the deviation of the ground level, while increasing the charging current (e.g., 304 in FIG. 3) in, for example, a stepwise manner.

In operation 540, the electronic device 101 according to an embodiment may determine the charging current based on the determined impedance. For example, the electronic device 101 may, in case that the impedance of the cable 203 deviates from a designated range, determine that the cable 203 is aged or not a designated genuine product. The electronic device 101 may, in case that the cable 203 is aged or not a designated genuine product, reduce a target value (e.g., a target charging current, or a maximum charging current). For example, the electronic device 101 may, in case that the cable 203 is aged or not a designated genuine product, configure the charging current to have a value less than a designated maximum value.

In operation 550, the electronic device 101 according to an embodiment may request the external device 202 to transmit the determined charging current. For example, the electronic device 101 may transmit the first signal 305 in consideration of the charging current determined during at least a portion of the period of transmitting the request of the PPS PDO. For example, the electronic device 101 may request the external device 202 to increase the charging current by about 50 mA to about 100 mA during at least a portion of the period of transmitting the request of the PPS PDO. The electronic device 101 may configure the target value of the charging current to be a value in consideration of the impedance of the cable 203 while increasing the charging current by about 50 mA to about 100 mA. The target value of the charging current in consideration of the impedance of the cable 203 may be configured to be a designated maximum value when the cable 203 is normal. The target value of the charging current in consideration of the impedance of the cable 203 may be configured to have a value smaller than the designated maximum value when the cable 203 is aged or not a designated genuine product.

FIG. 6 is a flowchart illustrating an example method by which an electronic device 101 compares a first signal 305 and a second signal 306 according to various embodiments.

Operations described in FIG. 6 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 6.

At least a portion of the operations illustrated in FIG. 6 may be omitted. At least some of the operations described with reference to other drawings in this disclosure may be added or inserted before or after at least some of the operations shown in FIG. 6.

According to an embodiment, at least some of the operations described in FIG. 6 may be performed sequentially.

According to an embodiment, at least some of the operations described in FIG. 6 may be performed in parallel (concurrently).

Hereinafter, with reference to FIGS. 6, 7 and 8 (which may be referred to as FIGS. 6 to 8), a method by which the electronic device 101 according to an embodiment compares the first signal 305 and the second signal 306 will be described. The operations described with reference to FIGS. 6 to 8 may be performed during a request period of the PPS PDO in which the electronic device 101 requests an increase in the charging current from the external device 202 by about 50 mA to about 100 mA. In an embodiment, the operations described with reference to FIGS. 6 to 8 may be performed during a period prior to the request period of the PPS PDO, during a request period of the 5V PDO, or during a request period of the 9V PDO.

In operation 610, according to an embodiment, the electronic device 101 (e.g., the electronic device 101 in FIG. 1 or the power receiving device 201 in FIG. 2) may identify the high voltage level (or high level) (e.g., VH1 in FIG. 4) of the first signal 305 output from the electronic device while performing communication with an external device (e.g., the power supply device 202 in FIG. 2) according to the PD communication protocol (e.g., power data objects (PDO) or programmable power supply (PPS)).

In operation 620, according to an embodiment, the electronic device 101 may identify the inverted high voltage level (or inverted high level) (e.g., VL2 or GND2 in FIG. 4) of the second signal 306 received from the external device 202. For example, the electronic device 101 may invert the potential of the second signal 306 using an inverter circuit (e.g., 710 in FIG. 7).

In operation 630, the electronic device 101 according to an embodiment may compare the high voltage level (or high level) of the first signal 305 and the inverted high voltage level (or high level) of the second signal 306.

In operation 640, the electronic device 101 according to an embodiment may determine the charging current and the impedance of the cable 203 based on a result of the comparison in operation 630. Operation 640 may be at least partially identical or substantially similar to operation 530 described with reference to FIG. 5.

According to an embodiment, the electronic device 101 according to an embodiment may compare the high voltage level (or high level) of the first signal 305 and the inverted high voltage level (or high level) of the second signal 306 to identify a degree of IR drop occurring in the cable 203. The electronic device 101 may, based on the degree of the IR drop occurring in the cable 203, estimate the impedance of the cable 203 and determine whether the estimated impedance of the cable 203 is within a designated range.

According to an embodiment, the electronic device 101 may transmit the first signal 305 requesting the charging current configured in consideration of the impedance of the cable 203 during at least a portion of the period of transmitting the request of the PPS PDO. For example, the electronic device 101 may request the external device 202 to increase the charging current by about 50 mA to about 100 mA during at least a portion of the period of transmitting the request of the PPS PDO. The electronic device 101 may configure the target value of the charging current to be a value in consideration of the impedance of the cable 203 while increasing the charging current by about 50 mA to about 100 mA. The target value of the charging current in consideration of the impedance of the cable 203 may be configured to be a designated maximum value when the cable 203 is normal. The target value of the charging current in consideration of the impedance of the cable 203 may be configured to have a value smaller than the designated maximum value when the cable 203 is aged or not a designated genuine product.

According to an embodiment, the electronic device 101 may, based on the inverted high voltage level of the second signal 306, estimate the impedance of the cable 203 and determine whether the estimated impedance of the cable 203 is within a designated range.

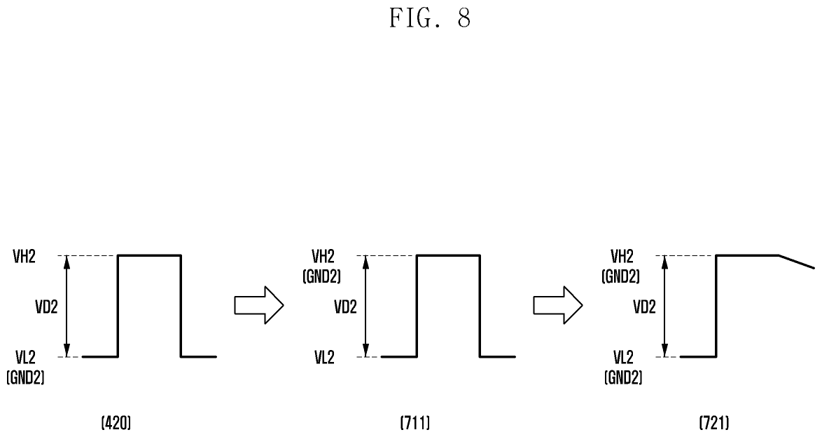

FIG. 7 is a block diagram illustrating an example configuration of example components of an electronic device 101 for converting a second signal 420 according to various embodiments. FIG. 8 is a diagram illustrating an example process in which an electronic device 101 converts a second signal 420 according to various embodiments.

Referring to FIG. 7, the electronic device 101 according to an embodiment may include an inverter circuit 710, delay circuit 720, or an analog to digital converter (ADC) 730 to identify the inverted high voltage level of the second signal 306.

According to an embodiment, the inverter circuit 710 may be configured to invert and output the potential of the received second signal 306. The inverter circuit 710 may invert the potential of the received second signal 306 to generate a first conversion signal 711 and provide the generated first conversion signal 711 to the delay circuit 720. For example, as shown in FIG. 8, the first conversion signal 711 may be a signal acquired by inverting the low voltage level VL2 of the second signal 306 into the high voltage level and inverting the high voltage level VH2 of the second signal 306 into the low voltage level.

According to an embodiment, the delay circuit 720 may be configured to receive the first conversion signal 711 from the inverter circuit 710 and output the received first conversion signal 711 with a delay. The delay circuit 720 may include at least one capacitor or at least one resistor, and the disclosure is not limited to the circuit configuration of the delay circuit 720. According to an embodiment, the delay circuit 720 may delay the first conversion signal 711 to generate a second conversion signal 721 and provide the generated second conversion signal 721 to the ADC 730. The delay circuit 720 may delay the first conversion signal 711 to allow the ADC 730 to measure a potential. For example, the first conversion signal 711 generated based on the second signal 306 operates at the level of several microseconds, and this communication speed is too fast for the ADC 730 to measure the potential. The delay circuit 720 may serve to delay the first conversion signal 711 so that the ADC 730 can measure the potential. For example, as shown in FIG. 8, the second conversion signal 721 may correspond to a signal acquired when VL2 corresponding to the high voltage level of the first conversion signal 711 is delayed for a predetermined time period.

The term “delay circuit 720” as used in various embodiments of the disclosure may be used interchangeably with terms such as peak detector.

According to an embodiment, the ADC 730 may be configured to receive the second conversion signal from the delay circuit 720 and convert the received second conversion signal into a third conversion signal 731 corresponding to a digital signal.

FIG. 9 is a flowchart illustrating an example operation in which an electronic device 101 determines an impedance of a cable 203 by comparing a high voltage level of each of a first signal 305 and a second signal 306 according to various embodiments.

Operations described in FIG. 9 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 9.

At least a portion of the operations illustrated in FIG. 9 may be omitted. At least some of the operations described with reference to other drawings in this disclosure may be added or inserted before or after at least some of the operations shown in FIG. 9.

According to an embodiment, at least some of the operations described in FIG. 9 may be performed sequentially.

According to an embodiment, at least some of the operations described in FIG. 9 may be performed in parallel (concurrently).

Hereinafter, with reference to FIG. 9, an operation in which the electronic device 101 according to an embodiment determines the impedance of the cable 203 by comparing the high voltage level of each of the first signal 305 and the second signal 306 will be described. The operations described with reference to FIG. 9 may be performed during a request period of the PPS PDO in which the electronic device 101 requests an increase in the charging current from the external device 202 by about 50 mA to about 100 mA. In an embodiment, the operations described with reference to FIG. 9 may be performed during a period prior to the request period of the PPS PDO, during a request period of the 5V PDO, or during a request period of the 9V PDO.

In operation 910, according to an embodiment, the electronic device 101 (e.g., the electronic device 101 in FIG. 1 or the power receiving device 201 in FIG. 2) may identify the high voltage level (or high level) (e.g., VH1 in FIG. 4) of the first signal 305 output from the electronic device while performing communication with an external device 202 (e.g., the power supply device 202 in FIG. 2) according to the PD communication protocol (e.g., power data objects (PDO) or programmable power supply (PPS)). Operation 910 may be at least partially identical to operation 610 described with reference to FIG. 6.

In operation 920, according to an embodiment, the electronic device 101 may identify the high voltage level (or high level) (e.g., VH2 in FIG. 4) of the second signal 306 received from the external device 202.

In operation 930, the electronic device 101 according to an embodiment may compare the high voltage level (or high level) of the first signal 305 and the high voltage level (or high level) of the second signal 306.

In operation 940, the electronic device 101 according to an embodiment may determine the charging current and the impedance of the cable 203 based on a result of the comparison in operation 930. Operation 940 may be at least partially identical or substantially similar to operation 530 described with reference to FIG. 5.

According to an embodiment, the electronic device 101 according to an embodiment may compare the high voltage level (or high level) of the first signal 305 and the high voltage level (or high level) of the second signal 306 to identify a degree of IR drop occurring in the cable 203. The electronic device 101 may, based on the degree of the IR drop occurring in the cable 203, estimate the impedance of the cable 203 and determine whether the estimated impedance of the cable 203 is within a designated range.

According to an embodiment, the electronic device 101 may transmit the first signal 305 requesting the charging current configured in consideration of the impedance of the cable 203 during at least a portion of the period of transmitting the request of the PPS PDO. For example, the electronic device 101 may request the external device 202 to increase the charging current by about 50 mA to about 100 mA during at least a portion of the period of transmitting the request of the PPS PDO. The electronic device 101 may configure the target value of the charging current to be a value in consideration of the impedance of the cable 203 while increasing the charging current by about 50 mA to about 100 mA. The target value of the charging current in consideration of the impedance of the cable 203 may be configured to be a designated maximum value when the cable 203 is normal. The target value of the charging current in consideration of the impedance of the cable 203 may be configured to have a value smaller than the designated maximum value when the cable 203 is aged or not a designated genuine product.

FIG. 10 is a flowchart illustrating an example operation in which an electronic device 101 determines an impedance of a cable 203 by comparing a low voltage level of each of a first signal 305 and a second signal 306 according to various embodiments.

Operations described in FIG. 10 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 10.

At least a portion of the operations illustrated in FIG. 10 may be omitted. At least some of the operations described with reference to other drawings in this disclosure may be added or inserted before or after at least some of the operations shown in FIG. 10.

According to an embodiment, at least some of the operations described in FIG. 10 may be performed sequentially.

According to an embodiment, at least some of the operations described in FIG. 10 may be performed in parallel (concurrently).

Hereinafter, with reference to FIG. 10, an operation in which the electronic device 101 according to an embodiment determines the impedance of the cable 203 by comparing the low voltage level of each of the first signal 305 and the second signal 306 will be described. The operations described with reference to FIG. 10 may be performed during a request period of the PPS PDO in which the electronic device 101 requests an increase in the charging current from the external device 202 by about 50 mA to about 100 mA. In an embodiment, the operations described with reference to FIG. 10 may be performed during a period prior to the request period of the PPS PDO, during a request period of the 5V PDO, or during a request period of the 9V PDO.

In operation 1010, according to an embodiment, the electronic device 101 (e.g., the electronic device 101 in FIG. 1 or the power receiving device 201 in FIG. 2) may identify the low voltage level (or low level) (e.g., VL1 in FIG. 4) of the first signal 305 output from the electronic device while performing communication with an external device (e.g., the power supply device 202 in FIG. 2) according to the PD communication protocol (e.g., power data objects (PDO) or programmable power supply (PPS)).

In operation 1020, according to an embodiment, the electronic device 101 may identify the low voltage level (or low level) (e.g., VL2 or GND2 in FIG. 4) of the second signal 306 received from the external device 202.

In operation 1030, the electronic device 101 according to an embodiment may compare the low voltage level (or low level) of the first signal 305 and the low voltage level (or low level) of the second signal 306.

In operation 1040, the electronic device 101 according to an embodiment may determine the charging current and the impedance of the cable 203 based on a result of the comparison in operation 1030. Operation 1040 may be at least partially identical or substantially similar to operation 530 described with reference to FIG. 5.

According to an embodiment, the electronic device 101 according to an embodiment may compare the low voltage level (or low level) of the first signal 305 and the low voltage level (or low level) of the second signal 306 to identify a degree of IR drop occurring in the cable 203. The electronic device 101 may, based on the degree of the IR drop occurring in the cable 203, estimate the impedance of the cable 203 and determine whether the estimated impedance of the cable 203 is within a designated range.

According to an embodiment, the electronic device 101 may transmit the first signal 305 requesting the charging current configured in consideration of the impedance of the cable 203 during at least a portion of the period of transmitting the request of the PPS PDO. For example, the electronic device 101 may request the external device 202 to increase the charging current by about 50 mA to about 100 mA during at least a portion of the period of transmitting the request of the PPS PDO. The electronic device 101 may configure the target value of the charging current to be a value in consideration of the impedance of the cable 203 while increasing the charging current by about 50 mA to about 100 mA. The target value of the charging current in consideration of the impedance of the cable 203 may be configured to be a designated maximum value when the cable 203 is normal. The target value of the charging current in consideration of the impedance of the cable 203 may be configured to have a value smaller than the designated maximum value when the cable 203 is aged or not a designated genuine product.

FIG. 11 is a flowchart illustrating an example operation in which an electronic device 101 determines an impedance of a cable 203 by comparing an amplitude of each of a first signal 305 and a second signal 306 according to various embodiments.

Operations described in FIG. 11 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 11.

At least a portion of the operations illustrated in FIG. 11 may be omitted. At least some of the operations described with reference to other drawings in this disclosure may be added or inserted before or after at least some of the operations shown in FIG. 11.

According to an embodiment, at least some of the operations described in FIG. 11 may be performed sequentially.

According to an embodiment, at least some of the operations described in FIG. 11 may be performed in parallel (concurrently).

Hereinafter, with reference to FIG. 11, an operation in which the electronic device 101 according to an embodiment determines the impedance of the cable 203 by comparing the amplitude of each of the first signal 305 and the second signal 306 will be described. The operations described with reference to FIG. 11 may be performed during a request period of the PPS PDO in which the electronic device 101 requests an increase in the charging current from the external device 202 by about 50 mA to about 100 mA. In an embodiment, the operations described with reference to FIG. 11 may be performed during a period prior to the request period of the PPS PDO, during a request period of the 5V PDO, or during a request period of the 9V PDO.

In operation 1110, according to an embodiment, the electronic device 101 (e.g., the electronic device 101 in FIG. 1 or the power receiving device 201 in FIG. 2) may identify the amplitude (e.g., VD1 in FIG. 4) of the first signal 305 output from the electronic device while performing communication with an external device (e.g., the power supply device 202 in FIG. 2) according to the PD communication protocol (e.g., power data objects (PDO) or programmable power supply (PPS)).

In operation 1120, according to an embodiment, the electronic device 101 may identify the amplitude (e.g., VD2 in FIG. 4) of the second signal 306 received from the external device 202.

In operation 1130, the electronic device 101 according to an embodiment may compare the amplitude of the first signal 305 and the amplitude of the second signal 306.

In operation 1140, the electronic device 101 according to an embodiment may determine the charging current and the impedance of the cable 203 based on a result of the comparison in operation 1130. Operation 1140 may be at least partially identical or substantially similar to operation 530 described with reference to FIG. 5.

According to an embodiment, the electronic device 101 according to an embodiment may compare the amplitude of the first signal 305 and the amplitude of the second signal 306 to identify a degree of IR drop occurring in the cable 203. The electronic device 101 may, based on the degree of the IR drop occurring in the cable 203, estimate the impedance of the cable 203 and determine whether the estimated impedance of the cable 203 is within a designated range.

According to an embodiment, the electronic device 101 may transmit the first signal 305 requesting the charging current configured in consideration of the impedance of the cable 203 during at least a portion of the period of transmitting the request of the PPS PDO. For example, the electronic device 101 may request the external device 202 to increase the charging current by about 50 mA to about 100 mA during at least a portion of the period of transmitting the request of the PPS PDO. The electronic device 101 may configure the target value of the charging current to be a value in consideration of the impedance of the cable 203 while increasing the charging current by about 50 mA to about 100 mA. The target value of the charging current in consideration of the impedance of the cable 203 may be configured to be a designated maximum value when the cable 203 is normal. The target value of the charging current in consideration of the impedance of the cable 203 may be configured to have a value smaller than the designated maximum value when the cable 203 is aged or not a designated genuine product.

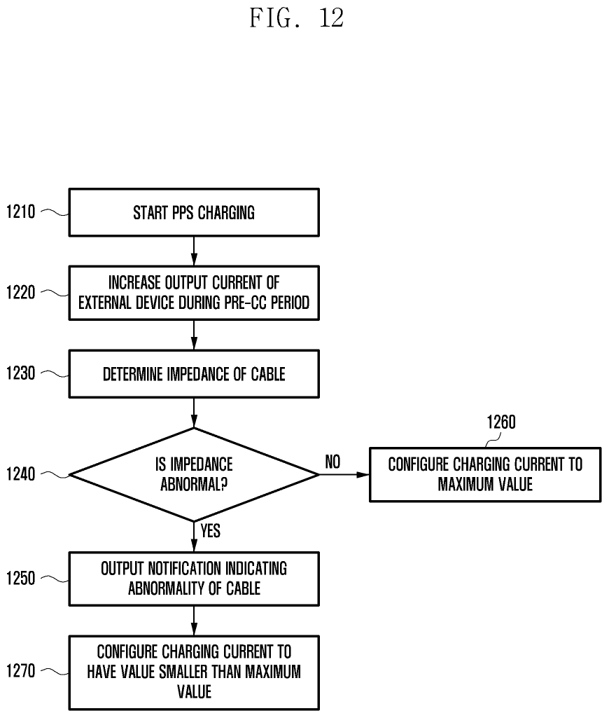

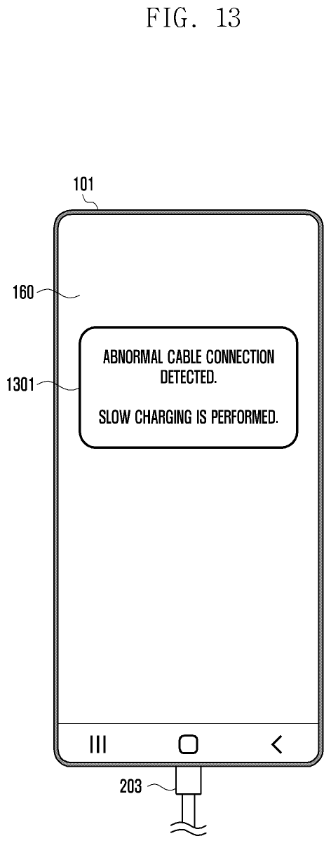

FIG. 12 is a flowchart illustrating an example operation of an electronic device 101 according to various embodiments. FIG. 13 is a diagram illustrating an example notification output from an electronic device 101 according to various embodiments.

Operations described in FIG. 12 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 12.

At least a portion of the operations illustrated in FIG. 12 may be omitted. At least some of the operations described with reference to other drawings in this disclosure may be added or inserted before or after at least some of the operations shown in FIG. 12.

According to an embodiment, at least some of the operations described in FIG. 12 may be performed sequentially.

According to an embodiment, at least some of the operations described in FIG. 12 may be performed in parallel (concurrently).

Hereinafter, an operation of the electronic device 101 according to an embodiment will be described with reference to FIGS. 12 and 13. The operations described with reference to FIGS. 12 and 13 may be performed during a request period of the PPS PDO in which the electronic device 101 requests an increase in the charging current from the external device 202 by about 50 mA to about 100 mA. In an embodiment, the operations described with reference to FIGS. 12 and 13 may be performed during a period prior to the request period of the PPS PDO, during a request period of the 5V PDO, or during a request period of the 9V PDO.

In operation 1210, according to an embodiment, the electronic device (e.g., the electronic device 101 in FIG. 1 or the power receiving device 201 in FIG. 2) may perform PPS charging in case that the external device (e.g., the power supply device 202 in FIG. 2) is identified as a device supporting the PPS. According to an embodiment, requests for a 5V PDO, a 9V PDO, and a PPS PDO for PPS charging may be transferred to the external device 202 through the first signal 305.

In operation 1220, the electronic device 101 according to an embodiment may request the external device 202 to increase the charging current by about 50 mA to about 100 mA in an initial period configured in the constant current (CC) mode, such as a pre-cc period.

In operation 1230, the electronic device 101 according to an embodiment may perform communication with the external device 202 (e.g., the power supply device 202 in FIG. 2) according to the PD communication protocol (e.g., power data objects (PDO) or programmable power supply (PPS)) during the pre-cc period. The electronic device 101 may compare a difference value of the potential of the first signal 305 output from the electronic device and the potential of the second signal 306 received from the external device 202 and determine the impedance of the cable 203, based on a result of the comparison. Operation 1230 may be similar or substantial identical to at least some operations described with reference to FIGS. 5 to 11. For example, operation 1230 may be at least partially identical or substantially similar to operation 530 described with reference to FIG. 5.

According to an embodiment, the electronic device 101 may measure a deviation of the ground level of the first signal 305 from the ground level of the second signal 306. According to an embodiment, the electronic device 101 may measure a ΔV value recognized at the power terminal 221 of the electronic device 101 when the charging current (e.g., 304 in FIG. 3) is increased in a stepwise manner while keeping the voltage requested from the external device 202 fixed in the pre-cc section, which is the early section of the PPS. In this case, the ΔV value may refer to “a voltage change at the power terminal 221—the deviation between the ground level of the first signal 305 and the ground level of the second signal 306 measured at the data terminal 223.” For example, while the voltage output by the external device 202 is fixed, the VBUS voltage at the power terminal 221 of the electronic device 101 gradually drops as the charging current (e.g., 304 in FIG. 3) increases. When the voltage output from the external device 202 is fixed, the impedance value of the cable (e.g., 203 in FIG. 2) may be calculated by calculating a voltage drop according to a current change amount in the electronic device 101.

According to an embodiment, when the charging current (e.g., 304 in FIG. 3) is increased in a stepwise manner in the pre-cc section, which is the early section of the PPS, an ADC (e.g., the ADC 730 in FIG. 7) included in the electronic device 101 may be used. According to an embodiment, the electronic device 10 may determine the deviation of the ground level of the first signal 305 and the ground level of the second signal 306 measured at the VBUS and data terminal 223 recognized at the power terminal 221, and then increase the charging current (e.g., 304 in FIG. 3) in a stepwise manner to determine the deviation of the ground level of the first signal 305 and the ground level of the second signal 306 measured at the VBUS and data terminal 223 recognized at the power terminal 221. According to an embodiment, the electronic device 101 may calculate the impedance of the cable 203 based on identifying a change in the VBUS potential difference and a change in the deviation of the ground level, while increasing the charging current (e.g., 304 in FIG. 3) in a stepwise manner.

In operation 1240, the electronic device 101 according to an embodiment may determine whether the determined impedance of the cable 203 is abnormal. For example, the electronic device 101 may, in case that the impedance of the cable 203 is within a designated range, determine that the cable 203 is normal. For example, the electronic device 101 may, in case that the impedance of the cable 203 deviates from a designated range, determine that the cable 203 is aged or not a designated genuine product.

According to an embodiment, the electronic device 101 may, in case that the impedance of the cable 203 has been determined to be abnormal (e.g., in case that a result of operation 1240 is yes), perform operation 1250.

According to an embodiment, the electronic device 101 may, in case that the impedance of the cable 203 has been determined to be normal (e.g., in case that a result of operation 1240 is no), perform operation 1260.

In operation 1250, the electronic device 101 according to an embodiment may output a notification indicating that the cable 203 is abnormal.

Referring to FIG. 13, the electronic device 101 according to an embodiment may display the notification 1301 through the display module 160 (e.g., the display module 160 in FIG. 1). For example, the notification 1301 may be output in the text form and may include a message such as “Abnormal cable 203 connection detected. Slow charging is performed.” According to an embodiment, the electronic device 101 may output the notification 1301 to provide, to the user, information indicating that since the cable 203 is aged or not a designated genuine product, fast charging is impossible.

According to various embodiments, the electronic device 101 may output the notification in the form of sound or voice.

In operation 1260, the electronic device 101 according to an embodiment may configure the charging current to a designated maximum value. For example, the electronic device 101 may configure the target value of the charging current requested from the external device 202 to be a value in consideration of the impedance of the cable 203. The target value of the charging current in consideration of the impedance of the cable 203 may be configured to be a designated maximum value when the cable 203 is normal. For example, the electronic device 101 may, in case that the cable 203 is normal, increase the charging current to a normal target current value of about 5 A.

In operation 1270, the electronic device 101 according to an embodiment may configure the charging current to a value smaller than the designated maximum value. For example, the electronic device 101 may configure the target value of the charging current requested from the external device 202 to be a value in consideration of the impedance of the cable 203. The target value of the charging current in consideration of the impedance of the cable 203 may be configured to have a value smaller than the designated maximum value when the cable 203 is aged or not a designated genuine product. For example, the electronic device 101 may, in case that the cable 203 is abnormal, increase the charging current to about 3 V to about 3.4 V lower than the normal target current value of about 5 A, but the disclosure is not limited thereto.

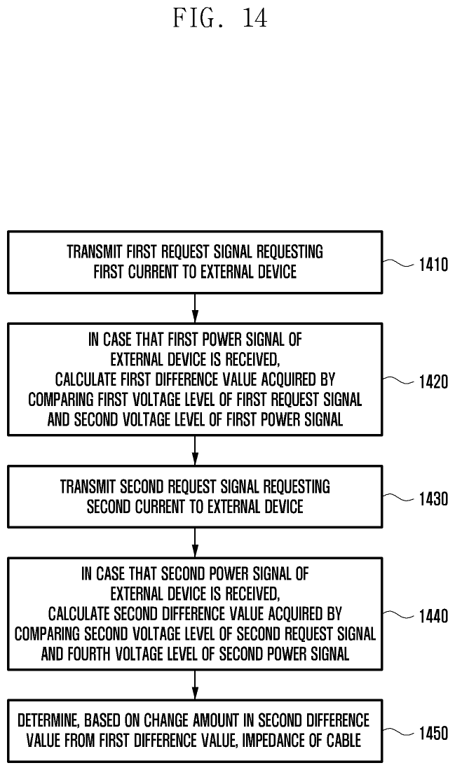

FIG. 14 is a flowchart illustrating an example operation in which an electronic device 101 determines an impedance of a cable 203 according to various embodiments.

Operations described in FIG. 14 may be performed by the instructions stored in the memory (e.g., the memory 130 in FIG. 1). For example, the instructions may, when executed by the processor (e.g., the processor 120 in FIG. 1), cause the electronic device (e.g., the electronic device 101 in FIG. 1 or the power receiving device 201 in FIG. 2) to perform operations described in FIG. 14.

At least a portion of the operations illustrated in FIG. 14 may be omitted. At least some of the operations described with reference to other drawings in this disclosure may be added or inserted before or after at least some of the operations shown in FIG. 14.

According to an embodiment, at least some of the operations described in FIG. 14 may be performed sequentially.

According to an embodiment, at least some of the operations described in FIG. 14 may be performed in parallel (concurrently).

Hereinafter, with reference to FIG. 14, an operation in which the electronic device 101 determines the impedance of the cable 203 according to an embodiment will be described. The operations described with reference to FIG. 14 may be performed during a request period of the PPS PDO in which the electronic device 101 requests an increase in the charging current from the external device 202 by about 50 mA to about 100 mA.

In operation 1410, according to an embodiment, the electronic device 101 (e.g., the electronic device 101 in FIG. 1 or the power receiving device 201 in FIG. 2) may transmit, to the external device 202 (e.g., the power supply device 202 in FIG. 2), a first request signal requesting a first current.

In operation 1420, the electronic device 101 according to an embodiment may receive a first power signal as a response to the first request signal from the external device 202. The first power signal is a power signal output by the external device 202 in response to the first request signal of the electronic device 101 and may include a first current. According to an embodiment, the electronic device 101 may, in case that the first power signal of the external device 202 is received, calculate a first difference value by comparing a first voltage level of the first request signal and a second voltage level of the received first power signal. For example, the electronic device 101 may measure a potential of the first power signal received through the power terminal (e.g., the power terminal 221 in FIG. 2) (e.g., the VBUS terminal) while fixing a potential (e.g., a high level, low level, or amplitude) of the first signal 305 (e.g., the first request signal) transmitted to the external device 202. For example, the electronic device 101 may compare a voltage level of the first signal 305 and a voltage level of the first power signal received through the power terminal 221 (e.g., the VBUS terminal) to calculate the first difference value.

In operation 1430, the electronic device 101 according to an embodiment may transmit, to the external device 202, a second request signal requesting a second current greater than the first current. For example, the electronic device 101 according to an embodiment may transmit, to the external device 202, the second request signal requesting the second current about 50 mA to about 100 mA higher than the first current.

In operation 1440, the electronic device 101 according to an embodiment may receive a second power signal as a response to the second request signal from the external device 202. The second power signal is a power signal output by the external device 202 in response to the second request signal of the electronic device 101 and may include a second current. According to an embodiment, the electronic device 101 may, in case that the second power signal of the external device 202 is received, calculate a second difference value by comparing a third voltage level of the second request signal and a fourth voltage level of the received second power signal. For example, the electronic device 101 may measure a potential of the second power signal received through the power terminal (e.g., the power terminal 221 in FIG. 2) (e.g., the VBUS terminal) while fixing a potential (e.g., a high level, low level, or amplitude) of the first signal 305 (e.g., the first request signal) transmitted to the external device 202. For example, the electronic device 101 may compare a voltage level of the first signal 305 and a voltage level of the second power signal received through the power terminal 221 (e.g., the VBUS terminal) to calculate the second difference value.

The voltage level of the second power signal may be subject to a greater IR drop compared to the voltage level of the first power signal as the charging current increases or decreases from the first current to the second current. Accordingly, the second difference value calculated in operation 1440 may be greater than the first difference value calculated in operation 1420.

In operation 1450, the electronic device 101 according to an embodiment may determine an impedance of the cable 203 based on an amount of change of the second difference value from the first difference value. For example, the second difference value calculated in operation 1440 may be greater than the first difference value calculated in operation 1420, and the electronic device 101 may estimate the impedance of the cable 203 by considering the amount of increase in the second current relative to the first current, and the amount of change in the second difference value from the first difference value.

According to various embodiments, the electronic device 101 may perform operation 1240 described with reference to FIG. 12 after performing operation 1450.

According to an example embodiment of the disclosure, an electronic device may include: a battery, a charging interface including at least one terminal configured to be connected to an external device through a cable, a first charger including a power converter comprising circuitry configured to increase a current supplied from the external device by a designated ratio to output the current and reduce a voltage supplied from the external device by the designated ratio to output the voltage, a second charger configured to function as a buck converter, a memory configured to store instructions, and at least one processor, comprising processing circuitry, wherein at least one processor, individually and/or collectively, is configured to execute the instruction and to cause the electronic device to: based on a connection with the external device being detected, perform designated communication with the external device through the cable, the designated communication including an operation in which the electronic device transmits a first signal and an operation in which the electronic device receives a second signal from the external device, calculate a difference value between a potential of the first signal and a potential of the second signal, determine, based on the calculated difference value and a change in a power voltage input to the electronic device, an impedance of the cable, determine, based on the determined impedance, a charging current, and request the external device to transmit the determined charging current.

At least one processor, individually and/or collectively, is configured to cause the electronic device to compare a high voltage level of the first signal and an inverted high voltage level of the second signal as an operation of calculating the different value between the potential of the first signal and the potential of the second signal.

At least one processor, individually and/or collectively, is configured to cause the electronic device to compare the high voltage level of the first signal and a high voltage level of the second signal as the operation of calculating the different value between the potential of the first signal and the potential of the second signal.

At least one processor, individually and/or collectively, is configured to cause the electronic device to compare a low voltage level of the first signal and a low voltage level of the second signal as the operation of calculating the different value between the potential of the first signal and the potential of the second signal.

At least one processor, individually and/or collectively, is configured to cause the electronic device to compare an amplitude of the first signal and an amplitude of the second signal as the operation of calculating the different value between the potential of the first signal and the potential of the second signal.

The electronic device may further include an inverter circuit configured to invert the second signal, a delay circuit configured to delay the second signal inverted by the inverter circuit, and an analog to digital converter (ADC) configured to convert the second signal delayed by the delay circuit into a digital signal.

At least one processor, individually and/or collectively, is configured to cause the electronic device to, based on the second signal converted by the ADC, calculate the difference value between the potential of the first signal and the potential of the second signal.

At least one processor, individually and/or collectively, is configured to cause the electronic device to: transmit a first request signal requesting a first current to the external device while the electronic device is configured in a constant current (CC) mode, based on a first power signal of the external device being received as a response to the first request signal, calculate a first difference value acquired by comparing a first voltage level of the first request signal and a second voltage level of the first power signal, transmit, to the external device, a second request signal requesting a second current greater than the first current, based on a second power signal of the external device being received as a response to the second request signal, calculate a second difference value acquired by comparing a third voltage level of the second request signal and a third voltage level of the second power signal, and determine the impedance of the cable, based on an amount of change of the second difference value from the first difference value.

The electronic device may further include: a display module including a display and at least one processor, individually and/or collectively, is configured to: cause the electronic device to determine whether the impedance of the cable is within a designated normal range, based on the impedance of the cable not being within the designated normal range, control the display module to display a notification indicating that the cable is abnormal, and configure the charging current to have a value less than a designated maximum value.

At least one processor, individually and/or collectively, is configured to cause the electronic device to: determine whether the impedance of the cable is within the designated normal range and based on the impedance of the cable being within the designated normal range, configure the charging current to the designated maximum value.

According to an example embodiment of the disclosure, a method of driving an electronic device may include: based on a connection with an external device through a cable being detected, performing designated communication with the external device through the cable, the designated communication including the electronic device transmitting a first signal and receiving a second signal from the external device, calculating a difference value between a potential of the first signal and a potential of the second signal, determining, based on the calculated difference, an impedance of the cable, determining, based on the determined impedance, a charging current, and requesting the external device to transmit the determined charging current.

The calculating the different value between the potential of the first signal and the potential of the second signal may include comparing a high voltage level of the first signal and an inverted high voltage level of the second signal.

The calculating the different value between the potential of the first signal and the potential of the second signal may include comparing a high voltage level of the first signal and a high voltage level of the second signal.

The calculating the different value between the potential of the first signal and the potential of the second signal may include comparing a low voltage level of the first signal and a low voltage level of the second signal.

The calculating the different value between the potential of the first signal and the potential of the second signal may include comparing an amplitude of the first signal and an amplitude of the second signal.

The electronic device may include an inverter circuit configured to invert the second signal, a delay circuit configured to delay the second signal inverted by the inverter circuit, and an analog to digital converter (ADC) configured to convert the second signal delayed by the delay circuit into a digital signal.

The driving method of the electronic device may include, based on the second signal converted by the ADC, calculating the difference value between the potential of the first signal and the potential of the second signal.

The driving method of the electronic device may include: transmitting a first request signal requesting a first current to the external device while the electronic device is configured in a constant current (CC) mode, based on a first power signal of the external device being received as a response to the first request signal, calculating a first difference value acquired by comparing a first voltage level of the first request signal and a second voltage level of the first power signal, transmitting, to the external device, a second request signal requesting a second current greater than the first current, an operation of, based on a second power signal of the external device being received as a response to the second request signal, calculating a second difference value acquired by comparing a third voltage level of the second request signal and a third voltage level of the second power signal, and determining the impedance of the cable, based on an amount of change of the second difference value from the first difference value.

The electronic device may further include a display module including display and the driving method of the electronic device may include: determining whether the impedance of the cable is within a designated normal range, an operation of, based on the impedance of the cable not being within the designated normal range, controlling the display module to display a notification indicating that the cable is abnormal, and configuring the charging current to have a value less than a designated maximum value.

According to an example embodiment, an electronic device may include a battery, an interface including a power terminal, a ground terminal, and a data terminal and configured to be connected to an external device through a cable, a detection circuit (e.g., an ADC connected to a VBUS, the inverter circuit in FIG. 7, and a circuit including a delay circuit, or a peak detector) configured to measure a signal associated with a voltage of the data terminal, at least one charging circuit configured to charge the battery using external power supplied through the power terminal and the ground terminal, a memory configured to store instructions, and at least one processor, comprising processing circuitry, individually and/or collectively, configured to execute the instructions and to cause the electronic device to: detect connection with the external device, receive a second signal from the external device through the cable, identify a voltage value associate with the second signal through the detection circuit, determine, based on the voltage value associated with the identified second signal, a charging current, and request the external device to transmit the determined charging current.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
a battery;
a charging interface comprising at least one terminal configured to be connected to an external device through a cable;
a first charger comprising a power converter configured to increase a current supplied from the external device by a designated ratio to output the current and reduce a voltage supplied from the external device by the designated ratio to output the voltage;
a second charger configured to function as a buck converter;
a memory configured to store instructions; and
at least one processor, comprising processing circuitry,
wherein at least one processor, individually and/or collectively, is configured to execute the instructions and to cause the electronic device to:
based on detecting a connection with the external device, perform designated communication with the external device through the cable, the designated communication comprising: transmitting a first signal by the electronic device and receiving a second signal from the external device by the electronic device;
calculate a difference value between a potential of the first signal and a potential of the second signal;
determine, based on the calculated difference value and a change in a power voltage input to the electronic device, an impedance of the cable;
determine, based on the determined impedance, a charging current; and
request the external device to transmit the determined charging current.

2. The electronic device of claim 1, wherein at least one processor, individually and/or collectively, is configured to cause the electronic device to, as the calculating of the difference value between the potential of the first signal and the potential of the second signal, compare a high voltage level of the first signal and an inverted high voltage level of the second signal.

3. The electronic device of claim 1, wherein at least one processor, individually and/or collectively, is configured to cause the electronic device to, as the calculating of the difference value between the potential of the first signal and the potential of the second signal, compare a high voltage level of the first signal and a high voltage level of the second signal.

4. The electronic device of claim 1, wherein at least one processor, individually and/or collectively, is configured to cause the electronic device to, as the calculating of the difference value between the potential of the first signal and the potential of the second signal, compare a low voltage level of the first signal and a low voltage level of the second signal.

5. The electronic device of claim 1, wherein at least one processor, individually and/or collectively, is configured to cause the electronic device to, as the calculating of the difference value between the potential of the first signal and the potential of the second signal, compare an amplitude of the first signal and an amplitude of the second signal.

6. The electronic device of claim 2, further comprising:
an inverter circuit configured to invert the second signal;
a delay circuit configured to delay the second signal inverted by the inverter circuit; and
an analog to digital converter (ADC) configured to convert the second signal delayed by the delay circuit into a digital signal.

7. The electronic device of claim 6, wherein at least one processor, individually and/or collectively, is configured to cause the electronic device to calculate, based on the second signal converted by the ADC, the difference value between the potential of the first signal and the potential of the second signal.

8. The electronic device of claim 1, wherein at least one processor, individually and/or collectively, is configured to cause the electronic device to:
transmit, to the external device, a first request signal requesting a first current while the electronic device is configured in a constant current (CC) mode;
based on receiving a first power signal of the external device in response to the first request signal, calculate a first difference value obtained by comparing a first voltage level of the first request signal and a second voltage level of the first power signal;
transmit, to the external device, a second request signal requesting a second current greater than the first current;
based on receiving a second power signal of the external device in response to the second request signal, calculate a second difference value obtained by comparing a third voltage level of the second request signal and a third voltage level of the second power signal; and
determine, based on an amount of change of the second difference value from the first difference value, the impedance of the cable.

9. The electronic device of claim 1, further comprising a display module, comprising a display,
wherein at least one processor, individually and/or collectively, is configured to cause the electronic device to:
determine whether the impedance of the cable is within a designated normal range;
based on the impedance of the cable not being within the designated normal range, control the display module to display a notification indicating that the cable is abnormal; and
configure the charging current to have a value less than a designated maximum value.

10. The electronic device of claim 1, wherein at least one processor, individually and/or collectively, is configured to cause the electronic device to:
determine whether the impedance of the cable is within a designated normal range; and
based on the impedance of the cable being within the designated normal range, configure the charging current to a designated maximum value.

11. A method of driving an electronic device, the method comprising:
based on detecting a connection with the external device through a cable, performing designated communication with the external device through the cable, the designated communication comprising transmitting a first signal by the electronic device and receiving a second signal by the electronic device from the external device;
calculating a difference value between a potential of the first signal and a potential of the second signal;
determining, based on the calculated difference value, an impedance of the cable;
determining, based on the determined impedance, a charging current; and
requesting the external device to transmit the determined charging current.

12. The method of claim 11, wherein the calculating of the difference value between the potential of the first signal and the potential of the second signal comprises comparing a high voltage level of the first signal and an inverted high voltage level of the second signal.

13. The method of claim 11, wherein the calculating of the difference value between the potential of the first signal and the potential of the second signal comprises comparing a high voltage level of the first signal and a high voltage level of the second signal.

14. The method of claim 11, wherein the calculating of the difference value between the potential of the first signal and the potential of the second signal comprises comparing a low voltage level of the first signal and a low voltage level of the second signal.

15. The method of claim 11, wherein the calculating of the difference value between the potential of the first signal and the potential of the second signal comprises comparing an amplitude of the first signal and an amplitude of the second signal.

16. The method of claim 12, wherein the electronic device comprises:
an inverter circuit configured to invert the second signal;
a delay circuit configured to delay the second signal inverted by the inverter circuit; and
an analog to digital converter (ADC) configured to convert the second signal delayed by the delay circuit into a digital signal.

17. The method of claim 16, comprising calculating, based on the second signal converted by the ADC, the difference value between the potential of the first signal and the potential of the second signal.

18. The method of claim 11, comprising:
transmitting, to the external device, a first request signal requesting a first current while the electronic device is configured in a constant current (CC) mode;
based on receiving a first power signal of the external device in response to the first request signal, calculating a first difference value obtained by comparing a first voltage level of the first request signal and a second voltage level of the first power signal;
transmitting, to the external device, a second request signal requesting a second current greater than the first current;
on receiving a second power signal of the external device in response to the second request signal, calculating a second difference value acquired by comparing a third voltage level of the second request signal and a third voltage level of the second power signal; and
determining, based on an amount of change of the second difference value from the first difference value, the impedance of the cable.

19. The method of claim 11, wherein the electronic device 101 further comprises a display module comprising a display, and
wherein the method comprises:
determining whether the impedance of the cable (203) is within a designated normal range; and
based on the impedance of the cable not being within the designated normal range, controlling the display module to display a notification indicating that the cable is abnormal; and
configuring the charging current to have a value less than a designated maximum value.

20. An electronic device comprising:
a battery;
an interface comprising a power terminal, a ground terminal, and a data terminal and configured to be connected to an external device through a cable;
a detection circuit configured to measure a signal associated with a voltage of the data terminal;
at least one charging circuit configured to charge the battery using external power supplied through the power terminal and the ground terminal;
a memory configured to store instructions; and
at least one processor, comprising processing circuitry,
wherein at least one processor, individually and/or collectively, is configured to execute the instructions and to cause the electronic device to:
detect a connection with the external device;
receive a second signal from the external device through the cable;
identify a voltage value associate with the second signal through the detection circuit;
determine, based on the identified voltage value associated with the second signal, a charging current; and
request the external device to transmit the determined charging current.
